(19) United States
(12) Patent Application Publication
(10) Pub. No.: US 2019/0103347 A1
(43) Pub. Date: Apr. 4, 2019

(54) ELECTRONIC COMPONENT ALIGNMENT DEVICE AND METHOD

(71) Applicants: Georg Seidemann, Landshut (DE); Andreas Wolter, Regensburg (DE); Stephan Stoeckl, Schwandorf (DE); Thomas Wagner, Regelsbach (DE)

(72) Inventors: Georg Seidemann, Landshut (DE); Andreas Wolter, Regensburg (DE); Stephan Stoeckl, Schwandorf (DE); Thomas Wagner, Regelsbach (DE)

(21) Appl. No.: 15/720,606

(22) Filed: Sep. 29, 2017

(51) Int. Cl. H01L 23/498; H01L 23/538; H01L 23/13; H01L 25/065; H05K 3/32; H05K 3/00

(52) U.S. Cl. CPC H01L 23/49833; H01L 23/5385; H01L 23/13; H01L 25/0655; H05K 2201/10674; H05K 3/32; H05K 3/007; H05K 2201/10522; H01L 23/5389

(57) ABSTRACT

A system and method for aligning components is disclosed. A system arranges a plurality of components in a first component alignment. The system places two L-shaped fine placement tools in a position surrounding the plurality of components, wherein the L-shaped fine placement tools include a plurality of pins. The system applies a force to the pins included in the two L-shaped fine placement tools to shift the plurality of components from the first component alignment to a second component alignment, wherein the second component alignment has less unused space than the first component alignment. The system removes the two L-shaped fine placement tools. The system attaches the plurality of components to a carrier arranged in the second component alignment.

### TECHNICAL FIELD

Embodiments described herein generally relate to component arrangement before they are placed on a carrier.

### BACKGROUND

Microelectronic devices operate using integrated circuits connected together with other components. As time has gone on, the size of the dies (and the size of the integrated circuit components) have shrunk dramatically. As such, it has become possible to integrate a large number of heterogeneous components in a single package. These components may be placed on a medium (e.g., a printed circuit board) to create complicated systems in a single package (or SiP).

However, having a large number of small components makes it difficult to efficiently pack the parts as close together as would be optimal. Indeed, the current solution, a pick-and-place machine, has a limited accuracy that may be cost-effectively achieved.

### BRIEF DESCRIPTION OF THE DRAWINGS

FIG. 1A is a diagram depicting an L-shaped fine placement tool in accordance with some example embodiments.

FIG. 1B is a diagram depicting an L-shaped fine placement tool as viewed from the side, in accordance with some example embodiments.

FIG. 2 is a diagram depicting a set of L-shaped fine placement tools arranged in a rectangular pattern and enabling fine adjustment of a plurality of parts/components in accordance with some example embodiments.

FIG. 3A is a diagram depicting a carrier for holding the L-shaped fine placement tools in accordance with some example embodiments.

FIG. 3B is a diagram depicting a carrier for holding the L-shaped fine placement tools that has been tilted in accordance with some example embodiments.

FIG. 4A is a diagram depicting a system for using an L-shaped fine placement tool to align a plurality of components for placement onto a carrier, in accordance with some example embodiments.

FIG. 4B is a diagram depicting a system for using an L-shaped fine placement tool to align a plurality of components for placement onto a carrier after force has been applied to the pins, in accordance with some example embodiments.

FIG. 4C is a diagram depicting a group of components that have been aligned using a system for using a L-shaped fine placement tool used to align a plurality of components for placement onto a carrier, in accordance with some example embodiments.

FIG. 5 shows a flow diagram of a method for using an L-shaped fine placement tool used to align a plurality of components for placement onto a carrier, in accordance with some example embodiments.

FIG. 6 shows a system that may incorporate aligning systems and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Systems in a package (SiP) are improved with increased density of components on the carrier (e.g., a printed circuit board) and more accurately placed components. Existing pick-and-place tools have a limited ability to reliably place components as close as would be optimal.

In one example, an alignment base is coupled to an assembly surface. A plurality of pins movably extend from the alignment base. An actuation system is then used to move at least some of the plurality of pins against a side of an electronic component to align the electronic component.

In one example, the alignment base includes two substantially orthogonal legs, formed in an L-shape. Various configurations of a system for aligning electronic components using an alignment base and pins are shown and discussed in examples below.

In one example, a pair of L-shaped fine placement tools may be used. The L-shaped fine placement tools consist of a two legs connected in the shape of an L. In one example, the legs are bars of paramagnetic material. In addition, the bars include holes into which movable pins are inserted.

In one example, each of the moveable pins has a magnetic end, enabling the pins to be moved with a magnetic field. In one example, two L-shaped fine placement tools may be placed such that they are adjacent to four sides of a collection of parts that are to be used in the system in a package.

Although a magnetic actuation system is described to actuate the pins, the invention is not so limited. Other examples of actuation may include, but are not limited to, pneumatic actuation, hydraulic actuation, electric actuation, mechanical actuation, etc.

In some example embodiments, the parts/components are placed in a rough placement using a pick-and-place tool (or other method). Then, using the L-shaped fine placement tools, a magnetic field is used to put inward pressure on the pins. The pins then push in and force the components as close together as possible.

In one example, because the L-shaped fine placement tools substantially surround the parts, the pins are able to push in from all sides, ensuring that the components are forced into their most compact arrangement. In some example embodiments, the L-shaped fine placement tools are removed and the components may be attached to carrier. A chosen carrier could include one of a printed circuit board (PCB), a ceramic substrate, a flip chip substrate, a wafer, or any planar support structure that is appropriate.

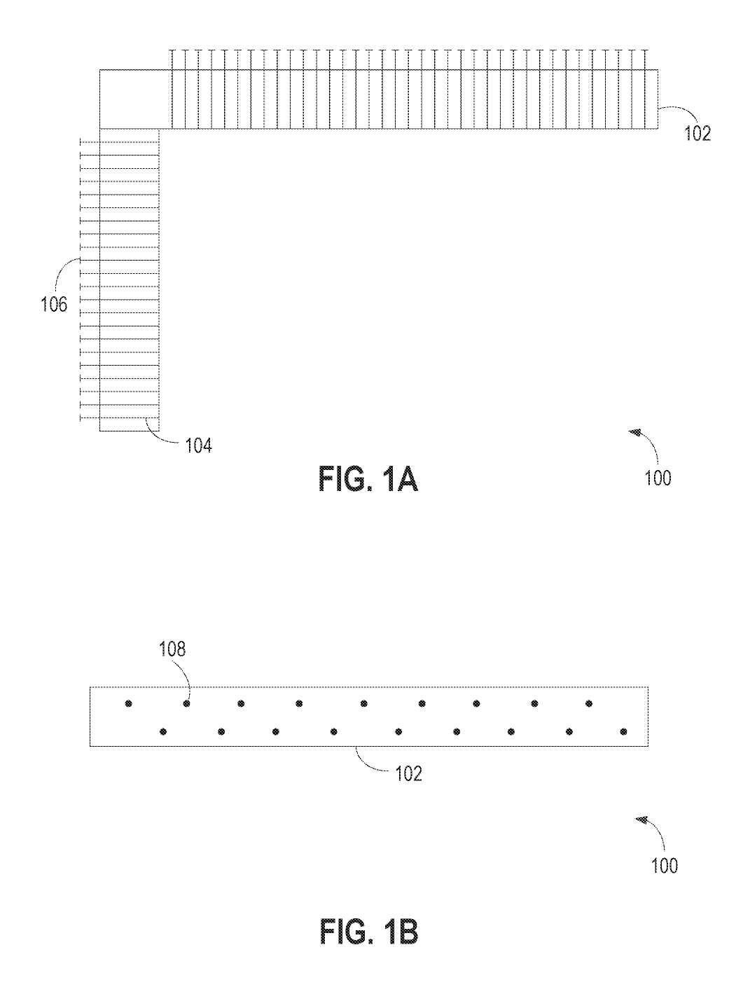

FIG. 1A is a diagram depicting a system for aligning electronic components 100 in accordance with some example embodiments. An alignment base 102 is shown with a plurality of pins 104 movably extending from the alignment base. The alignment base 102 is shown located on an assembly surface 114. An actuation system 112 is shown coupled to the alignment base 102 to move at least some of the plurality of pins 104 against a side of an electronic component to align the electronic component. As noted above, a number of possible actuation systems 112 may be used. In the following examples, a magnetic actuation system is discussed as one example.

In FIG. 1A the system 100 includes two rectangular alignment bases 102 arranged in an “L” shape. In some example embodiments, the rectangular sections 102 are permanently fixed together. In other example embodiments, the rectangular sections 102 may be moved in relation to each other as needed.

In some example embodiments, the alignment bases 102 include a series of pins 104 along their entire length. The pins 104 sit in holes in the alignment bases 102 such that they may move in and out. In some example embodiments, the pins 104 are evenly spaced out along the length of the alignment bases 102.

In some example embodiments, the ends of the pins 104 are magnetic, such that a magnetic field may result in the pins 104 moving inward or outward in response to an applied magnetic field.

FIG. 1B is a diagram depicting an alignment base 102 from the system 100 as viewed from the side, in accordance with some example embodiments. This side view of the alignment base 102 shows the placement of holes 108 along the side of the alignment base 102. Each hole 108 holds a pin 104 and enables movement of the pin 104 in and out of the hole 108. In one example, more than one row of holes 108 are included in the alignment base 102. The example of FIG. 113 shows a first row 103 and a second row 105. Although two rows with different heights are shown, the invention is not so limited. A single row, or more than two rows may also be used in other examples. Multiple rows at different heights have an advantage of being able to align electronic components of different heights using one set of alignment equipment.

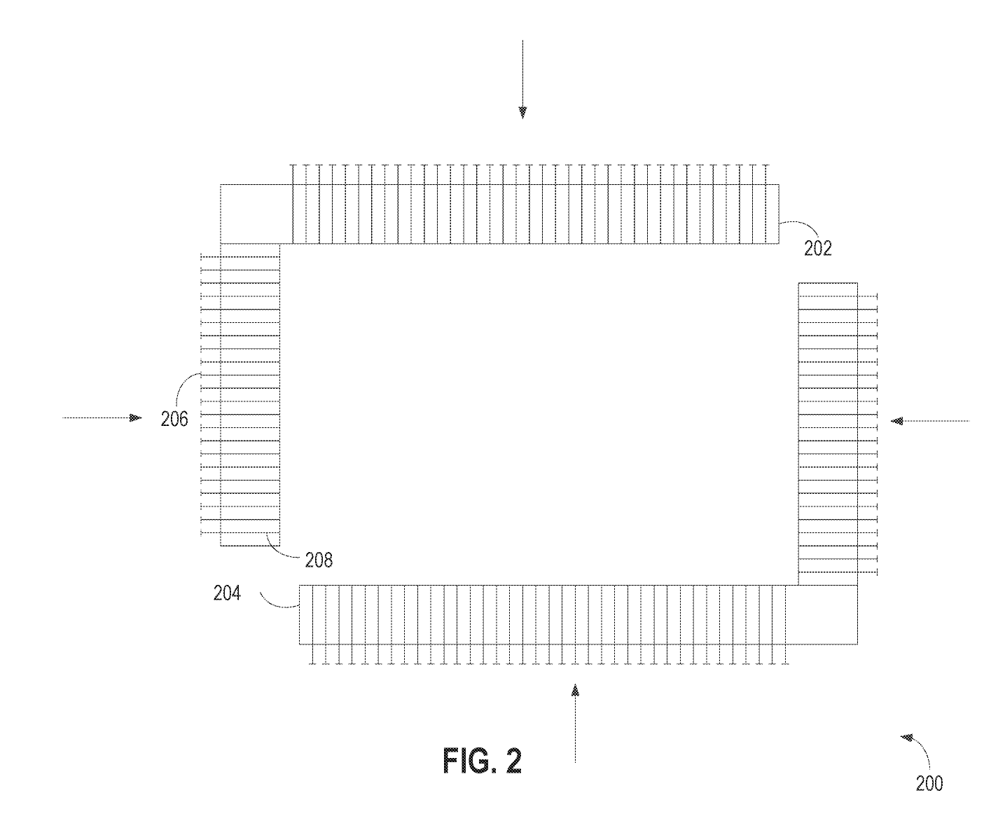

FIG. 2 is a diagram depicting a set of L-shaped fine placement tools 200 arranged in a rectangular pattern to enable fine adjustment of a plurality of parts/components in accordance with some example embodiments. As may be seen, the two L-shaped fine placement tools 202 and 204 are arranged such that they form a rectangle around a space.

In some example embodiments, each L-shaped fine placement tool 202, 204 includes a series of pins 208. In one example, each pin 208 has a head 206 that is magnetic. As a result, the pins 208 may be pushed towards the center from all four directions.

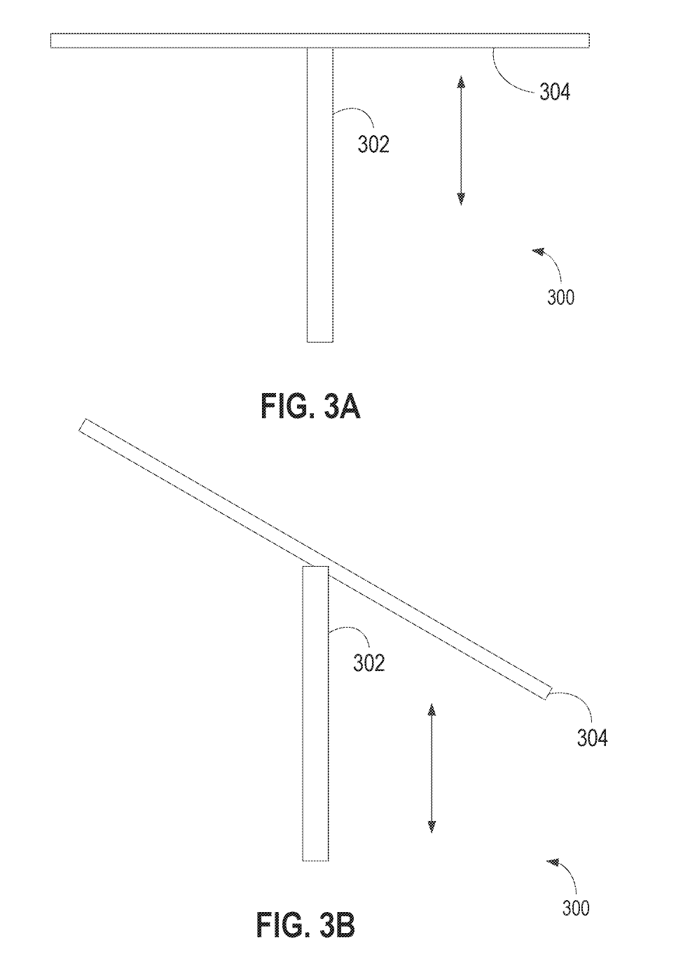

FIG. 3A is a diagram depicting a carrier 300 for holding the L-shaped fine placement tools (e.g., the tools 202, 204) in accordance with some example embodiments. In some example embodiments, the carrier 300 is a flat surface (e.g., like a table) that has the ability to tilt. In one example, the carrier 300 is similar to the assembly surface 114 from FIG. 1A.

In one example, the carrier 300 has at least two components. In some example embodiments, the carrier 300 has a leg or support 302 that supports the flat surface 304.

In some example embodiments, the flat surface 304 is configured to be able to tilt. By tilting, the carrier 300 allows gravity to assist in the placement of the components (in addition to the use of magnetism to push in the pins in the L-shaped fine placement tools).

FIG. 3B is a diagram depicting a carrier 300 for holding the L-shaped fine placement tools that has been tilted in accordance with some example embodiments. In this example, the flat surface 304 has been titled. In this configuration, any components on the flat surface 304 have gravity, in addition to pressure from pins, helping to ensure optimal component placement.

In some example embodiments, the carrier leg or support 302 remands in a fixed or near fixed position as the flat surface 304 tilts.

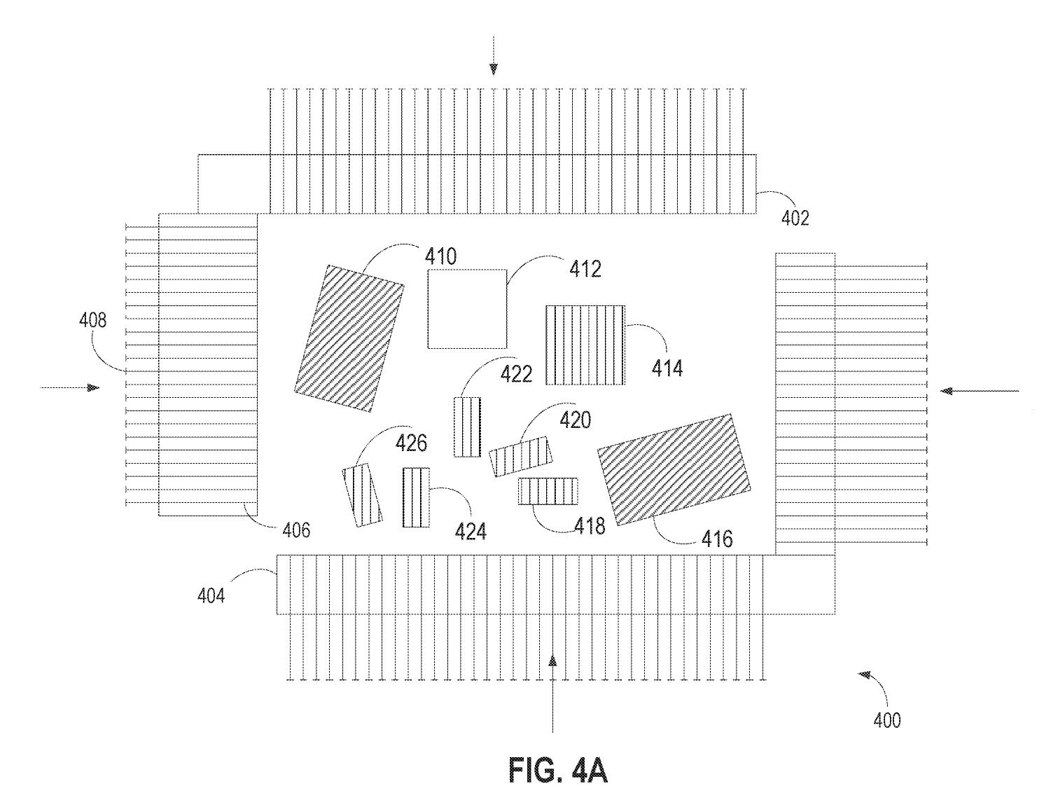

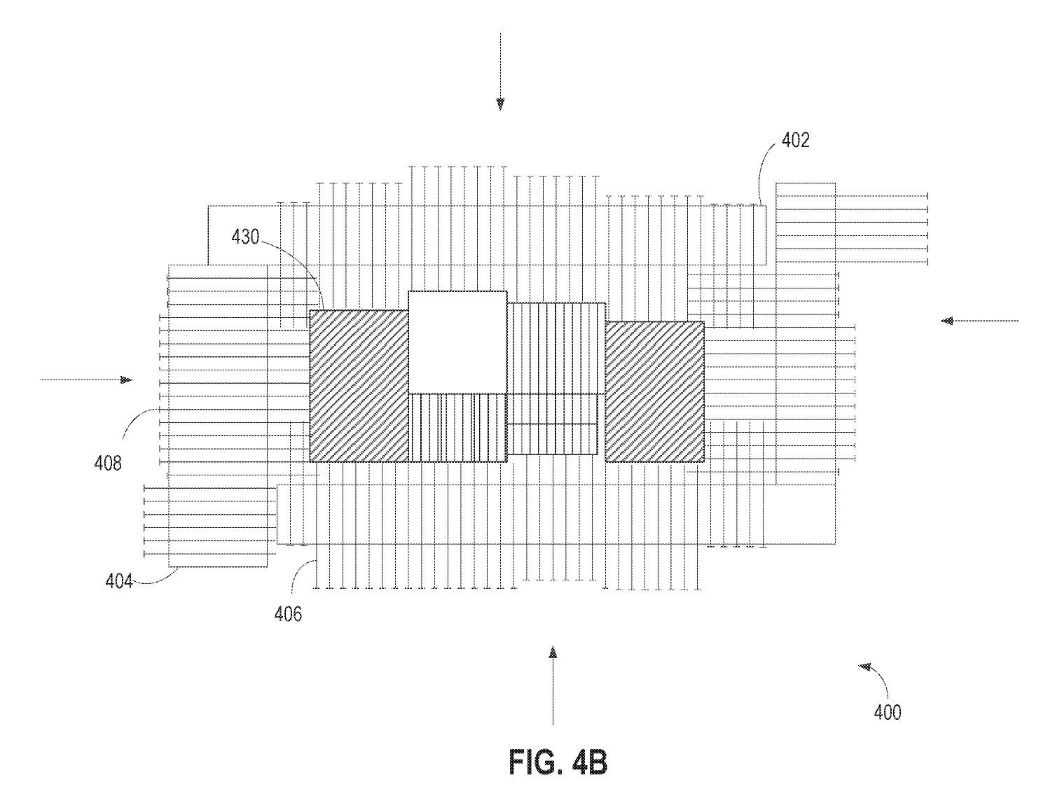

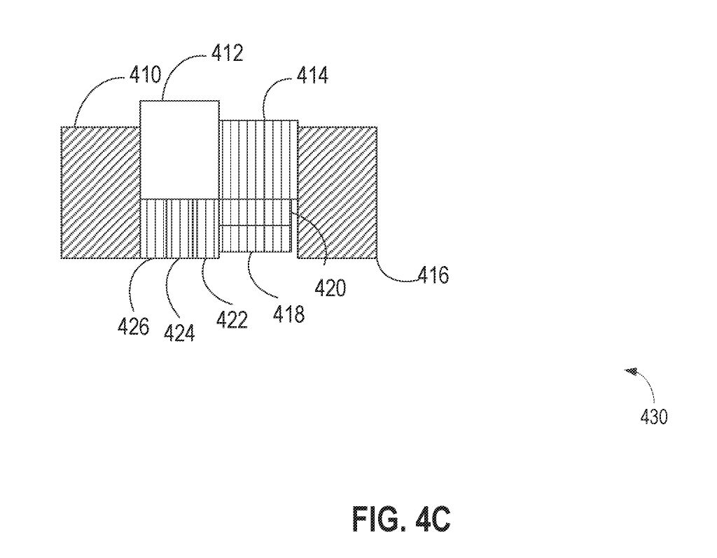

FIG. 4A is a diagram depicting a system 400 for using a L-shaped fine placement tool to align a plurality of components for placement onto a carrier, in accordance with some example embodiments.

In some example embodiments, a series of components 410 to 426 are loosely arranged based on a rough alignment. The components (410 to 426) are placed in the middle of two L-shaped fine placement tools 402 and 404 arranged in a rectangle.

In some example embodiments, the rough alignment is based on the placement of a pick-and-place process. This process only needs to place the components in a general area and the rest of the alignment will be accomplished by the L-shaped fine placement tools 402 and 404. As may be seen, the components 410 to 426 are not only not in an optimal spacing arrangement, the components 410 to 426 may also be misplaced rotationally.

Once the L-shaped fine placement tools 402 and 404 and the components 410 to 426 are in place, a force may be applied to the pins 406 using a magnetic field to affect the magnetic pin heads 408 or gravity (by tilting the carrier 300 as seen in FIG. 3).

FIG. 4B is a diagram depicting a system 400 for using an L-shaped fine placement tool to align a plurality of components for placement onto a carrier after force has been applied to the pins, in accordance with some example embodiments.

In this example, the pins 406 and their respective pin heads 408 have been pushed in. In some example embodiments, the pins 406 have pressed the components 410-426 in such a way that the components 410-426 are rotated correctly and sit closely together. This has been caused by applying a force to the pins 406 (either by actuation or through gravity). In some example embodiments, the force is applied in stages, such that a force is applied and then relaxed over a series of steps.

In this example, the group of components 430 is pressed together by pins 406. Each pin 406 is ultimately pushed in as far as the group of components 430 will allow. Thus, each of the pins 406 is pushed in a different amount.

FIG. 4C is a diagram depicting a group of components 430 that have been aligned using a system for using a L-shaped fine placement tool to align a plurality of components for placement onto a carrier, in accordance with some example embodiments.

As may be seen, all the components 410 to 426 have been correctly rotated and aligned with a minimum amount of empty space between them. In some example embodiments, the L-shaped fine placement tools 402 and 404 are removed and the components 410 to 426 are attached to a carrier to be used as part of a system in a package (SiP).

Although four orthogonal alignment bases are shown in many of the examples, above, the invention is not so limited. For example, a single alignment base may be used with fixed walls being located opposite to the pins in the alignment base. Two orthogonal alignment bases may be used with two orthogonal fixed walls located opposite to the two orthogonal alignment bases to form a rectangle. Other examples may not use orthogonal alignment bases or orthogonal fixed walls. A chosen geometry will depend on the desired end assembly configuration.

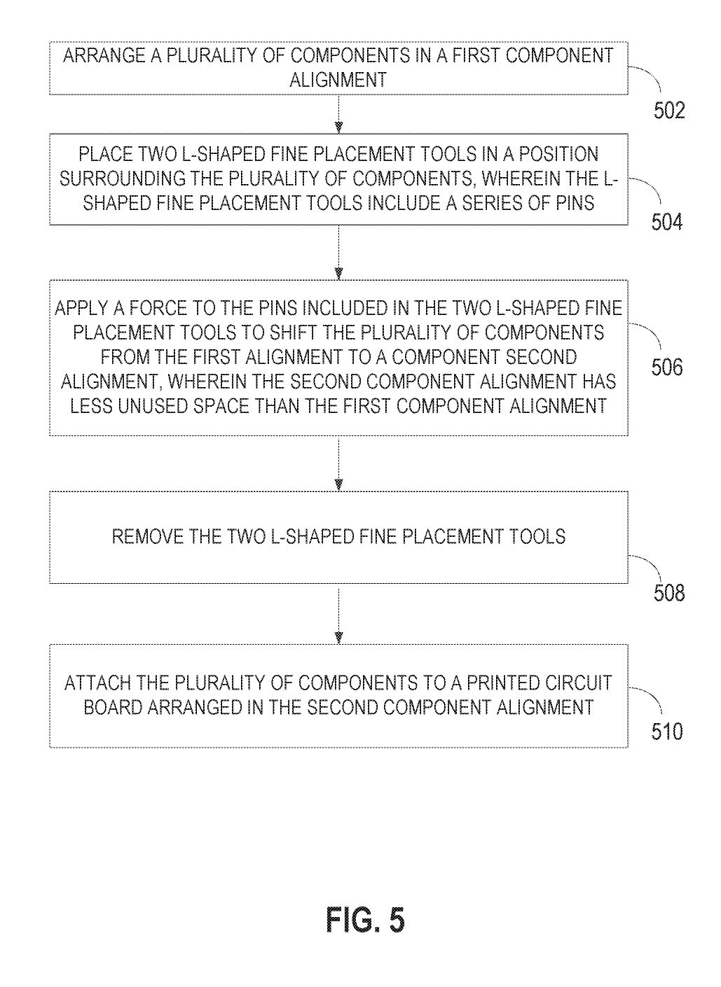

FIG. 5 shows a flow diagram of a method for using an L-shaped fine placement tool to align a plurality of components for placement onto a carrier, in accordance with some example embodiments.

In some example embodiments, a plurality of components are arranged (operation 502) in a first component alignment. In some example embodiments, the plurality of components are arranged in the first component alignment using a pick-and-place process.

In some example embodiments, two L-shaped fine placement tools are placed (504) in a position surrounding the plurality of components, wherein the L-shaped fine placement tools include a series of pins. In some example embodiments, the L-shaped fine placement tools are arranged in a rectangular configuration around the plurality of components.

In some example embodiments, the each pin in the plurality of pins includes a magnetic head. In some example embodiments, the components and L-shaped fine placement tools are placed on a carrier, wherein the carrier may be tilted.

In some example embodiments, a force is applied (506) to the pins included in the two L-shaped fine placement tools to shift the plurality of components from the first alignment to a second component alignment, wherein the second component alignment has less unused space than the first component alignment.

In some example embodiments, applying a force to the pins included in the two L-shaped fine placement tools comprises generating an external magnetic field to apply force to the magnetic heads of the pins. In some example embodiments, the carrier on which the components and the L-shaped fine placement tools are placed is tilted such that gravity exerts force on at least some of the pins. In addition, when the carrier is tilted, gravity also acts directly on the components such that they move closer together. In some example embodiments, gravity on the components is the principal force moving the components. In some example embodiments, the carrier can be mechanically vibrated such that the components are be shifted more easily. In some example embodiments, little vibrations are generated by a source such as a tactic engine) to generate slight movements of the components, such that the vibrations initialize the first movement of the components in combination with gravity.

In some example embodiments, applying a force to the pins includes magnetizing the L-shaped bars so that the bars themselves produce a field acting on the nail heads. For this purpose the bars would have to consist of a ferromagnetic and soft magnetic material like the core of a transformer or of an electromagnet.

In other example embodiments, applying a force to the pins can include producing a magnetic field internally by L-shaped bars consisting of a permanent magnetic material. In this example embodiment, the magnetic field cannot be switched and the L-shaped bars would be moved in plane to reduce the enclosed area with the components

In some example embodiments, the two L-shaped fine placement tools are removed (508) and the plurality of components are attached (510) to a carrier arranged in the second component alignment.

In some example embodiments, the L-shaped fine placement tools are initially connected to the carrier with the rest of the components. The L-shaped fine placement tools can then be removed before he carrier is used in the final electrical product.

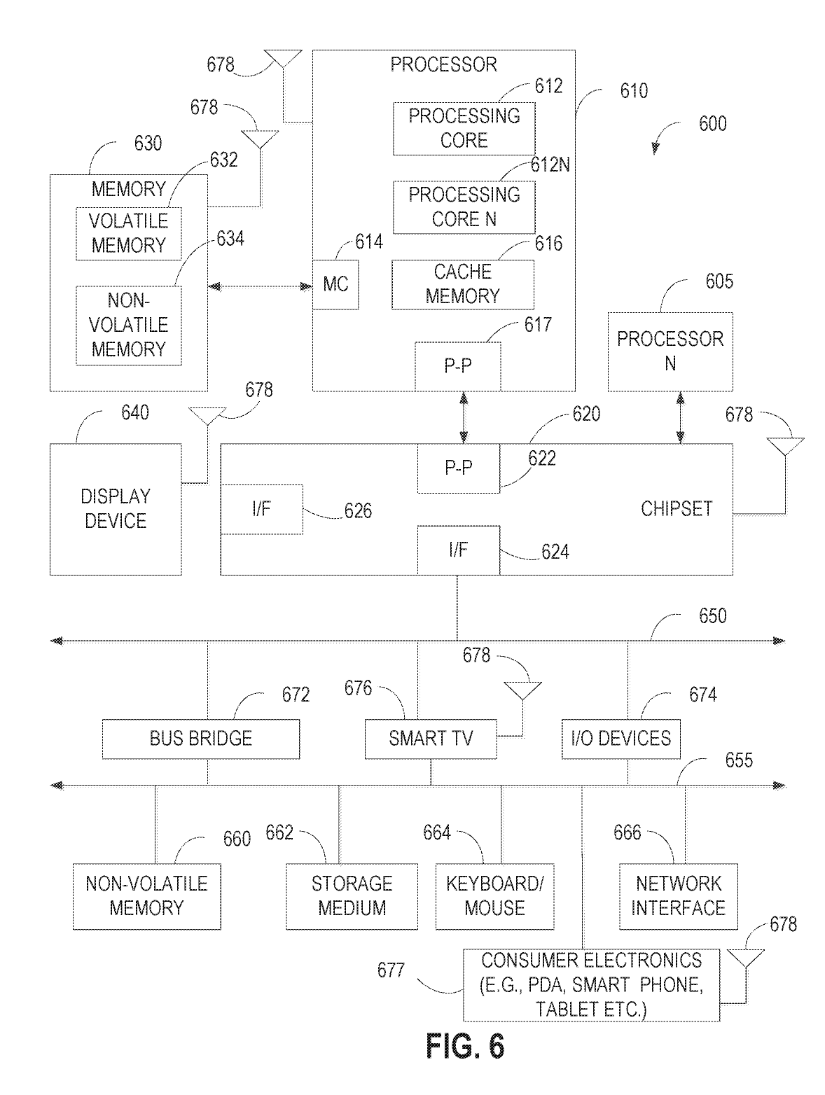

FIG. 6 illustrates a system level diagram, depicting an example of an electronic device (e.g., system) that may include devices formed using the systems and/or methods described above. For example devices may include multiple electronic components arranged using systems and/or methods described above. FIG. 6 may also illustrate a system level diagram of an electronic device used to execute examples of the methods described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 is a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

To better illustrate the method and apparatuses disclosed herein, a non-limiting list of embodiments is provided here:

Example 1 includes a system for aligning electronic components. The system includes an assembly surface, an alignment base located on the assembly surface, a plurality of pins movably extending from the alignment base, and an actuation system to move at least some of the plurality of pins against a side of an electronic component to align the electronic component.

Example 2 includes the system of example 1, further including a pick and place system to form a rough arrangement of electronic components on the assembly surface before alignment of the electronic components.

Example 3 includes the system of any one of examples 1-2, wherein the alignment base includes two substantially orthogonal legs.

Example 4 includes the system of any one of examples 1-3, wherein the alignment base is a first alignment base, and further including a second alignment base opposite the first alignment base.

Example 5 includes the system of any one of examples 1-4, wherein the first alignment base includes two substantially orthogonal legs, and wherein the second alignment base includes two substantially orthogonal legs, the first alignment base and the second alignment base forming opposed corners of a rectangle.

Example 6 includes the system of any one of examples 1-5, wherein the plurality of pins includes two rows of pins at different heights.

Example 7 includes the system of any one of examples 1-6, wherein the actuation system includes a magnetic actuation system.

Example 8 includes the system of any one of examples 1-7, wherein the magnetic actuation system includes magnetic heads on each of the plurality of pins that are actuated by a magnetic coil in the alignment base.

Example 9 includes a method of aligning components. The method includes arranging a plurality of components in a rough component alignment on an assembly surface adjacent to an alignment base located on the assembly surface, actuating a plurality of pins to extend from the alignment base to align the plurality of components from a rough alignment to a second alignment, and attaching the plurality of components to a carrier arranged in the second alignment.

Example 10 includes the method of example 9, wherein actuating a plurality of pins includes actuating one or more magnetic heads.

Example 11 includes the method of any one of examples 9-10, further including removing the alignment base from the assembly surface after arrangement in the second alignment,

Example 12 includes the method of any one of examples 9-11, further including tilting the assembly surface.

Example 13 includes the method of any one of examples 9-12, wherein actuating a plurality of pins to extend from the alignment base includes actuating a plurality of pins to extend from an alignment base that includes two substantially orthogonal legs.

Example 14 includes the method of any one of examples 9-13, wherein actuating a plurality of pins to extend from the alignment base includes actuating a plurality of pins to extend from a pair of opposing alignment bases.

Example 15 includes the method of any one of examples 9-14, wherein actuating a plurality of pins to extend from a pair of opposing alignment bases includes actuating a plurality of pins to extend from a pair of opposing L-shaped alignment bases arranged as corners of a rectangle.

Example 16 includes the method of any one of examples 9-15, further including horizontally shilling at least one of the opposing L-shaped alignment bases so that the area enclosed by the L-shaped alignment bases is reduced prior to actuating the plurality of pins.

Example 17 includes the method of any one of examples 9-16, wherein actuating a plurality of pins to extend from a pair of opposing alignment bases includes tilting the assembly surface such that gravity exerts a force on at least some of the pins.

Example 18 includes the method of any one of examples 9-17, further including picking and placing the plurality of components in the rough component alignment on the assembly surface prior to actuating the plurality of pins.

### Term Usage

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to airy single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled,

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. A system for aligning electronic components, comprising:
an assembly surface;
an alignment base located on the assembly surface;
a plurality of pins movably extending from the alignment base; and
an actuation system to move at least some of the plurality of pins against a side of an electronic component to align the electronic component.

2. The system of claim 1, further including a pick and place system to form a rough arrangement of electronic components on the assembly surface before alignment of the electronic components.

3. The system of claim I, wherein the alignment base includes two substantially orthogonal legs.

4. The system of claim 1, wherein the alignment base is a first alignment base, and further including a second alignment base opposite the first alignment base.

5. The system of claim 4, wherein the first alignment base includes two substantially orthogonal legs, and wherein the second alignment base includes two substantially orthogonal legs, the first alignment base and the second alignment base forming opposed corners of a rectangle.

6. The system of claim 1, wherein the plurality of pins includes two rows of pins at different heights.

7. The system of claim 1, wherein the actuation system includes a magnetic actuation system.

8. The system of claim 7, wherein the magnetic actuation system includes magnetic heads on each of the plurality of pins that are actuated by a magnetic coil in the alignment base.

9. A method of aligning components, the method comprising:
arranging a plurality of components in a rough component alignment on an assembly surface adjacent to an alignment base located on the assembly surface;
actuating a plurality of pins to extend from the alignment base to align the plurality of components from a rough alignment to a second alignment; and
attaching the plurality of components to a carrier arranged in the second alignment.

10. The method of claim 9, wherein actuating a plurality of pins includes actuating one or more magnetic heads.

11. The method of claim 9, further including removing the alignment base from the assembly surface after arrangement in the second alignment.

12. The method of claim 9, further including tilting the assembly surface.

13. The method of claim 9, wherein actuating a plurality of pins to extend from the alignment base includes actuating a plurality of pins to extend from an alignment base that includes two substantially orthogonal legs.

14. The method of claim 9, wherein actuating a plurality of pins to extend from the alignment base includes actuating a plurality of pins to extend from a pair of opposing alignment bases.

15. The method of claim 14, wherein actuating a plurality of pins to extend from a pair of opposing alignment bases includes actuating a plurality of pins to extend from a pair of opposing L-shaped alignment bases arranged as corners of a rectangle.

16. The method of claim 15, further including horizontally shifting at least one of the opposing L-shaped alignment bases so that the area enclosed by the L-shaped alignment bases is reduced prior to actuating the plurality of pins.

17. The method of claim 9, wherein actuating a plurality of pins to extend from a pair of opposing alignment bases includes tilting the assembly surface such that gravity exerts a force on at least some of the pins.

18. The method of claim 9, further including picking and placing the plurality of components in the rough component alignment on the assembly surface prior to actuating the plurality of pins.
